(19) United States
(12) Patent Application Publication
(10) Pub. No.: US 2008/0248408 A1
(43) Pub. Date: Oct. 9, 2008

(54) Photomask and Method for Forming a Non-Orthogonal Feature on the Same

(76) Inventors: Susan S. MacDonald, Georgetown, TX (US); David Mellenthin, Austin, TX (US)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 12/064,453

(22) PCT Filed: Sep. 6, 2006
(86) PCT No.: PCT/US06/34698

§ 371 Date: Feb. 21, 2008

Related U.S. Application Data
(60) Provisional application No. 60/714,560, filed on Sep. 7, 2005.

(51) Int. Cl. G03F 1/00

(52) U.S. Cl. 430/5

(57) ABSTRACT

A photomask and method for forming a non-orthogonal feature on the photomask are provided. A method for forming a non-orthogonal feature on a photomask blank includes providing a mask layout file including a primitive shape and fracturing the primitive shape to create a plurality of writeable shapes in a mask pattern file. A non-orthogonal feature formed by the writeable shapes is formed on a photomask blank by using a lithography system to image the writeable shapes from the mask pattern file onto a resist layer of the photomask blank.

### CROSS-REFERENCE TO RELATED APPLICATIONS

This application is a U.S. national stage application of International Application No. PCT/US2006/034698 filed Sep. 6, 2006, which designates the United States of America, and claims priority to U.S. Provisional Application Ser. No. 60/714,560 filed Sep. 7, 2005, the contents of which are hereby incorporated by reference in their entirety.

### TECHNICAL FIELD

This invention relates in general to photolithography and, more particularly to a photomask and a method for forming a non-orthogonal feature on the same.

### BACKGROUND

As device manufacturers continue to produce smaller and more complicated devices, photomasks used to fabricate these devices continue to require a wider range of capabilities. Photomasks, also known as reticles or masks, typically consist of substrates that have a patterned layer formed on the substrate. The patterned layer typically includes a pattern formed in an absorber material (e.g., chrome) that represents an image that may be transferred onto a wafer in a lithography system. For some applications the devices may require the formation of non-orthogonal features. As feature sizes of devices decrease, it becomes more difficult to create complex features having non-orthogonal designs.

Previous techniques for creating non-orthogonal features (e.g., circular features) having critical dimensions greater than approximately 300 nanometers (nm) include modeling the features as thirty-two sided polygons. However, as the dimensions of the features required to fabricate smaller devices decrease below approximately 300 nm, the large number of exposures required to write the small features and the decreased resolution make these techniques ineffective. Another technique for features having dimensions less than approximately 120 nm uses a step and flash imprint lithography (SFIL) process. With smaller dimensions, the non-orthogonal features may be modeled as squares such that the features will be written as circles on a photomask. However, at sizes greater than approximately 120 nm the square features may be written accurately as squares, rather than the desired non-orthogonal features.

### SUMMARY OF THE DISCLOSURE

In accordance with teachings of the present disclosure, disadvantages and problems associated with generating non-orthogonal features on a photomask have been substantially reduced or eliminated. In a particular embodiment, primitive shapes are used in a mask layout to create non-orthogonal features on a photomask.

In accordance with one embodiment, a method for forming a non-orthogonal feature on a photomask blank includes providing a mask layout file including a primitive shape and fracturing the primitive shape to create a plurality of writeable shapes in a mark pattern file. A non-orthogonal feature formed by the writeable shapes is formed on a photomask blank by using a lithography system to image the writeable shapes from the mask pattern file onto a resist layer of the photomask blank.

In accordance with another embodiment, a method for forming a non-orthogonal feature on a photomask includes exposing a resist layer of a photomask blank with a first portion of a primitive shape and exposing the resist layer with at least a second portion of the primitive shape located adjacent to the first portion. The resist layer is developed to form a non-orthogonal feature formed by the first and second portions of the primitive shape having critical dimensions between approximately 120 and approximately 300 nm.

In accordance with a further embodiment of the present disclosure, a photomask for forming a non-orthogonal feature on a surface includes a substrate and a patterned layer formed on at least a portion of the substrate. The non-orthogonal feature is formed in the pattern layer with a lithography system by using a primitive shape fractured into at least two writeable shapes.

### BRIEF DESCRIPTION OF THE DRAWINGS

A more complete and thorough understanding of the present embodiments and advantages thereof may be acquired by referring to the following description taken in conjunction with the accompanying drawings, in which like reference numbers indicate like features, and wherein:

FIG. 1A illustrates a cross-sectional view of a photomask assembly according to teachings of the present disclosure;

FIG. 1B illustrates a top view of a photomask according to teachings of the present disclosure;

FIG. 2A illustrates a circular feature included in a mask layout file according to the prior art;

FIG. 2B illustrates a circular feature fractured into writeable shapes in a mask pattern file according to the prior art;

FIG. 3A illustrates a square feature included in a mask layout file according to the prior art;

FIG. 3B illustrates a square feature fractured into writeable shapes in a mask pattern file according to the prior art;

FIG. 3C illustrates a square feature formed on a photomask according to the prior art;

FIG. 4A illustrates a cross feature included in a mask layout file according to teachings of the present disclosure;

FIG. 4B illustrates a cross feature fractured into writeable shapes in a mask pattern file according to teachings of the present disclosure;

FIG. 4C illustrates a cross feature formed on a photomask according to teachings of the present disclosure;

FIG. 5A illustrates a five-figure cross feature included in a mask layout file according to teachings of the present disclosure;

FIG. 5B illustrates a five-figure cross feature fractured into writeable shapes in a mask pattern file according to teachings of the present disclosure;

FIG. 5C illustrates a five-figure cross feature formed on a photomask according to teachings of the present disclosure;

FIG. 6A illustrates a hexagon feature included in a mask layout file according to teachings of the present disclosure;

FIG. 6B illustrates a hexagon feature fractured into writeable shapes in a mask pattern file according to teachings of the present disclosure;

FIG. 6C illustrates a hexagon feature formed on a photomask according to teachings of the present disclosure;

FIG. 7A illustrates an octagon feature included in a mask layout file according to teachings of the present disclosure;

FIG. 7B illustrates an octagon feature fractured into writeable shapes in a mask pattern file according to teachings of the present disclosure;

FIG. 7C illustrates an octagon feature formed on a photomask according to teachings of the present disclosure;

FIG. 8A illustrates an example technique for sizing a hexagon feature in a mask layout file according to teachings of the present disclosure; and

FIG. 8B illustrates an example technique for sizing a hexagon feature in a mask layout file according to teachings of the present disclosure.

### DETAILED DESCRIPTION

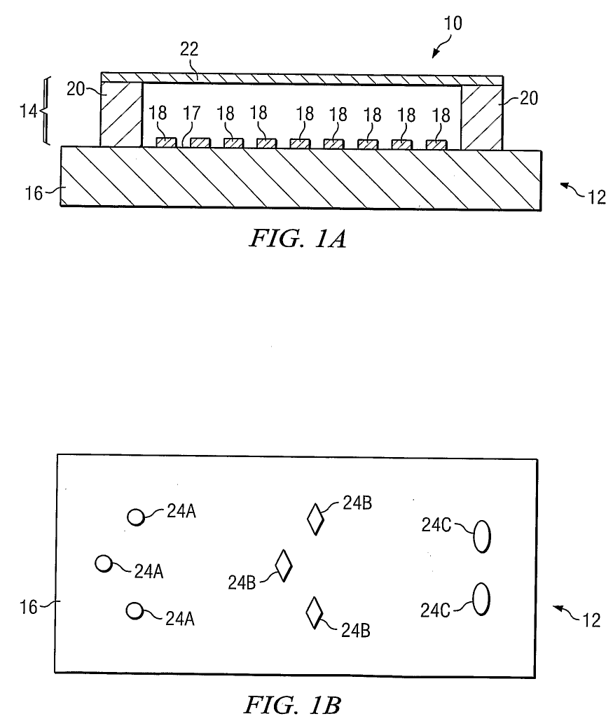

Preferred embodiments of the present disclosure and their advantages are best understood by reference to FIGS. 1 through 8, where like numbers are used to indicate like and corresponding parts.

FIG. 1 illustrates a cross-sectional view of an example photomask assembly 10. Photomask assembly 10 includes pellicle assembly 14 mounted on photomask 12. Substrate 16 and patterned layer 18 form photomask 12, otherwise known as a mask or reticle, that may have a variety of sizes and shapes, including but not limited to round, rectangular, or square. Photomask 12 may also be any variety of photomask types, including, but not limited to, a one-time master, a five-inch reticle, a six-inch reticle, a nine-inch reticle or any other appropriately sized reticle that may be used to project an image of a circuit pattern onto a semiconductor wafer. Photomask 12 may further be a binary mask, a phase shift mask (PSM) (e.g., an alternating aperture phase shift mask, also known as a Levenson type mask), an optical proximity correction (OPC) mask or any other type of mask suitable for use in a lithography system. In other embodiments, photomask 12 may be a step and flash imprint lithography (SFIL) template used to form an imprint of a pattern in a polymerizable fluid composition that solidifies to form a device on a wafer. The template may be a semi-transparent material, and the polymerizable fluid may be solidified by exposure to a radiation source in order to form the device on the wafer.

Photomask 12 includes patterned layer 18 formed on a top surface of substrate 16 that, when exposed to electromagnetic energy in a lithography system, projects a pattern onto a surface of a semiconductor wafer (not expressly shown). Substrate 16 may be a transparent material such as quartz, synthetic quartz, fused silica, magnesium fluoride (MgF₂), calcium fluoride (CaF₂), or any other suitable material that transmits at least seventy-five percent (75%) of incident light having a wavelength between approximately 10 nanometers (nm) and approximately 450 nm. In an alternative embodiment, substrate 16 may be a reflective material such as silicon or any other suitable material that reflects greater than approximately fifty percent (50%) of incident light having a wavelength between approximately 10 nm and 450 nm.

Patterned layer 18 may be a metal material such as chrome, chromium nitride, a metallic oxy-carbo-nitride (e.g., MOCN, where M is selected from the group consisting of chromium, cobalt, iron, zinc, molybdenum, niobium, tantalum, titanium, tungsten, aluminum, magnesium, and silicon), or any other suitable material that absorbs electromagnetic energy with wavelengths in the ultraviolet (UV) range, deep ultraviolet (DUV) range, vacuum ultraviolet (VUV) range and extreme ultraviolet range (EUV). In an alternative embodiment, patterned layer 18 may be a partially transmissive material, such as molybdenum silicide (MoSi), which has a transmissivity of approximately one percent (1%) to approximately thirty percent (30%) in the UV, DUV, VUV and EUV ranges.

Frame 20 and pellicle film 22 may form pellicle assembly 14. Frame 20 is typically formed of anodized aluminum, although it could alternatively be formed of stainless steel, plastic or other suitable materials that do not degrade or outgas when exposed to electromagnetic energy within a lithography system. Pellicle film 22 may be a thin film membrane formed of a material such as nitrocellulose, cellulose acetate, an amorphous fluoropolymer, such as TEFLON® AF manufactured by E. I. du Pont de Nemours and Company or CYTOP® manufactured by Asahi Glass, or another suitable film that is transparent to wavelengths in the UV, DUV, EUV and/or VUV ranges. Pellicle film 22 may be prepared by a conventional technique such as spin casting.

Pellicle film 22 protects photomask 12 from contaminants, such as dust particles, by ensuring that the contaminants remain a defined distance away from photomask 12. This may be especially important in a lithography system. During a lithography process, photomask assembly 10 is exposed to electromagnetic energy produced by a radiant energy source within the lithography system. The electromagnetic energy may include light of various wavelengths, such as wavelengths approximately between the I-line and G-line of a Mercury arc lamp, or DUV, VUV or EUV light. In operation, pellicle film 22 is designed to allow a large percentage of the electromagnetic energy to pass through it. Contaminants collected on pellicle film 22 will likely be out of focus at the surface of the wafer being processed and, therefore, the exposed image on the wafer should be clear. Pellicle film 22 formed in accordance with the teachings of the present disclosure may be satisfactorily used with all types of electromagnetic energy and is not limited to lightwaves as described in this application.

Photomask 12 may be formed from a photomask blank using a standard lithography process. In a lithography process, a mask pattern file that includes data for patterned layer 18 may be generated from a mask layout file. In one embodiment, the mask layout file may include polygons that represent transistors and electrical connections for an integrated circuit. The polygons in the mask layout file may further represent different layers of the integrated circuit when it is fabricated on a semiconductor wafer. For example, a transistor may be formed on a semiconductor wafer with a diffusion layer and a polysilicon layer. The mask layout file, therefore, may include one or more polygons drawn on the diffusion layer and one or more polygons drawn on the polysilicon layer. In the same or alternative embodiments, the mask layout file may include polygons or shapes that represent features to be fabricated in and/or upon magnetic memory devices, micro-electrical mechanical systems (MEMS), biological MEMS (bio-MEMS), and/or optics devices.

In accordance with the present disclosure, the polygons of the mask layout file may be primitive shapes, including, but not limited to, squares, rectangles, hexagons, octagons, crosses and any combination thereof. Primitive shapes used in a mask layout file are not limited to those listed, and may include any number of similarly-designed features.

The polygons for each layer may be converted into a mask pattern file that represents one layer of an integrated circuit. In such an application, each mask pattern file may be used to generate a photomask for the specific layer. In some embodiments, the mask pattern file may include more than one layer of the integrated circuit such that a photomask may be used to image features from more than one layer onto the surface of a semiconductor wafer. In the same or alternative embodiments, the polygons for each layer may represent a feature to be fabricated in and/or upon magnetic memory devices, micro-electrical mechanical systems (MEMS), biological MEMS (bio-MEMS), and/or optics devices.

The desired pattern may be imaged into a resist layer of the photomask blank using a laser, electron beam or X-ray lithography system. In one embodiment, a laser lithography system uses an argon-ion laser that emits light having a wavelength of approximately 364 nanometers (nm). In alternative embodiments, the laser lithography system uses lasers emitting light at wavelengths from approximately 150 nm to approximately 300 nm. In other embodiments, a 25 keV or 50 keV electron beam lithography system uses a lanthanum hexaboride or thermal field emission source. In the same or alternative embodiments, an electron beam lithography system may be a vector-shaped electronic beam lithography tool. In further embodiments, different electron beam lithography systems may be used. Photomask 12 may be fabricated by developing and etching exposed areas of the resist layer to create a pattern, etching the portions of patterned layer 18 not covered by resist, and removing the undeveloped resist to create patterned layer 18 over substrate 16.

FIG. 1B illustrates a top view of photomask 12 that includes non-orthogonal features 24 in accordance with an embodiment of the present disclosure. In the illustrated embodiment, photomask 12 includes substrate 16 and non-orthogonal features 24a, 24b and 24c (generally referred to as non-orthogonal features 24) formed in patterned layer 18. In one embodiment, non-orthogonal features 24 may be represented by exposed portions of substrate 16. In another embodiment, non-orthogonal features 24 may be represented by remaining portions of the absorber material used to form patterned layer 18.

Non-orthogonal features 24 may be formed using primitive shapes included in the mask layout file. Each of these primitive shapes may be fractured into multiple writeable shapes, such as rectangles or trapezoids, when each layer of the mask layout file is converted into a mask pattern file. The mask pattern file may be imaged onto a photomask blank and the blank may be developed and etched to form a photomask including non-orthogonal features 24. In one embodiment, non-orthogonal features 24a may be circular features that may be formed by using a hexagon feature drawn in a mask layout file. In another embodiment, non-orthogonal features 24b may be oval and/or elliptical features formed by using a stretched octagon feature drawn in a mask layout file. In an additional embodiment, non-orthogonal features 24c may be diamond features formed by using a cross feature drawn in a mask layout file. In other embodiments, any other suitable non-orthogonal features may be formed on photomask 12 by using different primitive shapes drawn in a mask layout file.

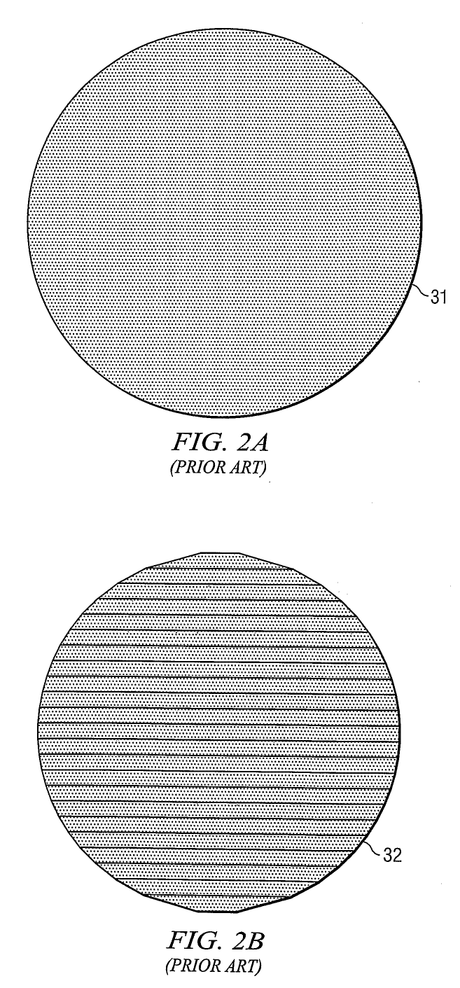

FIG. 2A illustrates a conventional representation of circular feature 31 in a mask layout file. In the illustrated embodiment, circular feature 31 may have a diameter of approximately 174 nm. In other embodiments, circular feature 31 may generally have critical dimensions (e.g., a diameter) between approximately 120 nm and approximately 300 nm.

FIG. 2B illustrates circular feature 31 shown in FIG. 2A after being fractured to create writeable image 32 in a mask pattern file. Writeable image 32 may be fractured into writeable shapes in the mask pattern file in order to form a feature on a photomask. In the illustrated embodiment, writeable image 32 has been fractured into twenty-three trapezoids. In a conventional fracturing process, the number of writeable shapes that a feature will fracture into may not be easily predictable and a circular feature having dimensions only slightly larger than those of the current example may fracture into a variable number of writeable shapes each time that the feature is written on a photomask.

Each writeable shape may represent an exposure or “shot” of a lithography system used to write the pattern on the photomask. Generally, a feature requiring more exposures will require more time to write. Writeable image 32, therefore, may require at least twenty-three exposures of the lithography system to form circular feature 31 on photomask 12. Thus, circular feature 31 and similarly sized non-orthogonal features may require a significant amount of time to create during the lithography process using standard techniques, which can increase production costs.

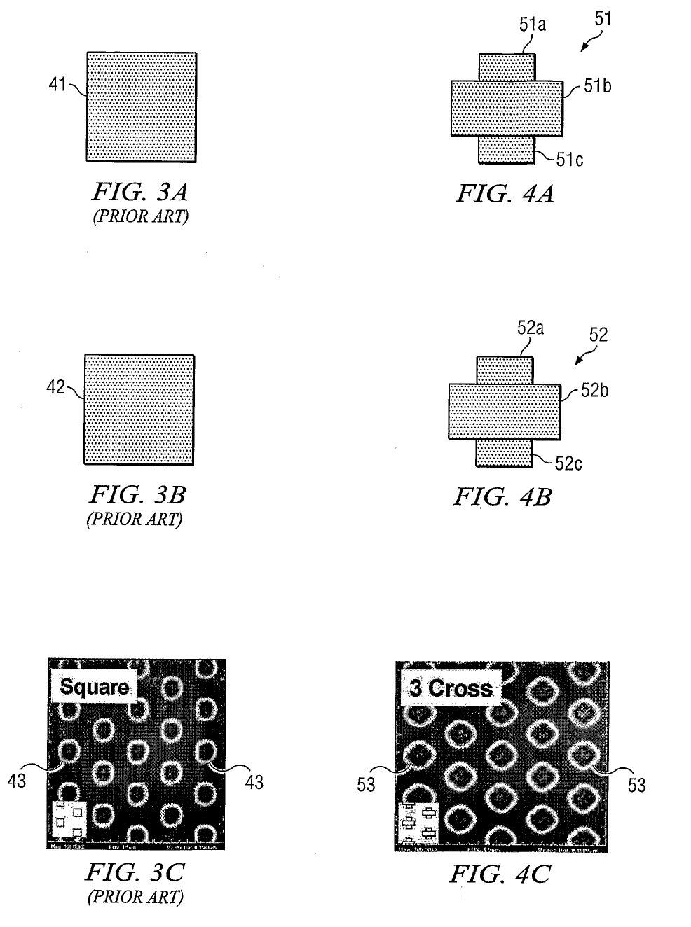

FIGS. 3A through 3C illustrate square feature 41 at various steps during a process to form a non-orthogonal feature on photomask 12. Specifically, FIG. 3A illustrates a conventional representation of square feature 41 in a mask layout file. In one embodiment, square feature 41 may have sides with lengths of less than approximately 120 nm.

FIG. 3B illustrates square feature 41 shown in FIG. 3A after being fractured to create writeable image 42 in a mask pattern file. Writeable image 42 may be fractured into multiple writeable shapes in the mask pattern file in order to form a feature on a photomask. Because square feature 41 is a simple square, it may be fractured into a single writeable shape that is similar to the originally drawn feature in the mask layout file. Square feature 41, combined with any number of other features, may be converted into a mask pattern file representing a layer of a device to be created. The shapes included in mask pattern file may be written on a photomask blank as described above in reference to FIG. 1.

FIG. 3C illustrates square feature 41 formed on a photomask. In the illustrated embodiment, a mask layout file including multiple square features 41 in an offset pattern was used to form a patterned layer including non-orthogonal features 43 on a photomask substrate. At sufficiently smaller sizes, such as side lengths less than approximately 120 nm, writeable image 42 may print as non-orthogonal feature 43 that is substantially circular. This is particularly true of features created using an SFIL template. However, writeable feature 42 may print as a square at approximately 300 nm. Thus, while imaging a circular feature as a square figure on a photomask may be more effective as the feature size decreases, it is not an effective method at dimensions of between approximately 120 and approximately 300 nm.

FIG. 4A illustrates cross feature 51 included in a mask layout file. Cross feature 51 may be a primitive shape created by drawing three rectangles 51a, 51b and 51c either as shown or rotated. For example, cross feature 51 may be created by drawing rectangle 51b oriented vertically and two smaller rectangles 51a and 51c on either side of first rectangle 51b. In another embodiment, cross feature 51 may be drawn as one rectangle overlaid on a second rectangle. Cross feature 51 may have critical dimensions, such as length and width of rectangles 51a, 51b and 51c, ranging from approximately 120 nm to approximately 300 nm. Cross feature 51 may also be drawn such that the length and width of rectangles 51a, 51b and 51c vary independently of one another and are not approximately equal.

FIG. 4B illustrates cross feature 51 shown in FIG. 4A after being fractured to create writeable image 52 in a mask pattern file. In one embodiment, cross feature 51 may consistently fracture into three writeable shapes 52a, 52b and 52c (e.g. rectangles) to form writeable image 52. The exact configuration of writeable shapes may vary in different embodiments of the disclosure. For example, writeable image 52 may be fractured into a rectangle oriented vertically and two smaller rectangles on either side of first rectangle. In another embodiment, writeable image 52 may be fractured into a large rectangle 52b oriented horizontally and two smaller rectangles 52a and 52c located above and below first rectangle 52b with the same result. In other embodiments, writeable image 52 may fracture into two overlapping rectangles, where one rectangle is oriented horizontally and one rectangle is oriented vertically. A lithography system using a mask pattern file containing writeable image 52, therefore, may use as few as two exposures to print cross feature 51 on photomask 12.

FIG. 4C illustrates cross feature 51 formed on a photomask. In the illustrated embodiment, a mask pattern file including multiple cross features 51 in an offset pattern was used to form a patterned layer including non-orthogonal features 53 on a photomask substrate. At sizes between approximately 120 nm and approximately 300 nm, writeable image 52 may print as non-orthogonal feature 53 that approximates a diamond in shape but has rounded points. Thus, cross feature 51 in a mask layout file may be used to create a diamond-like feature or slight variations of that shape on a photomask.

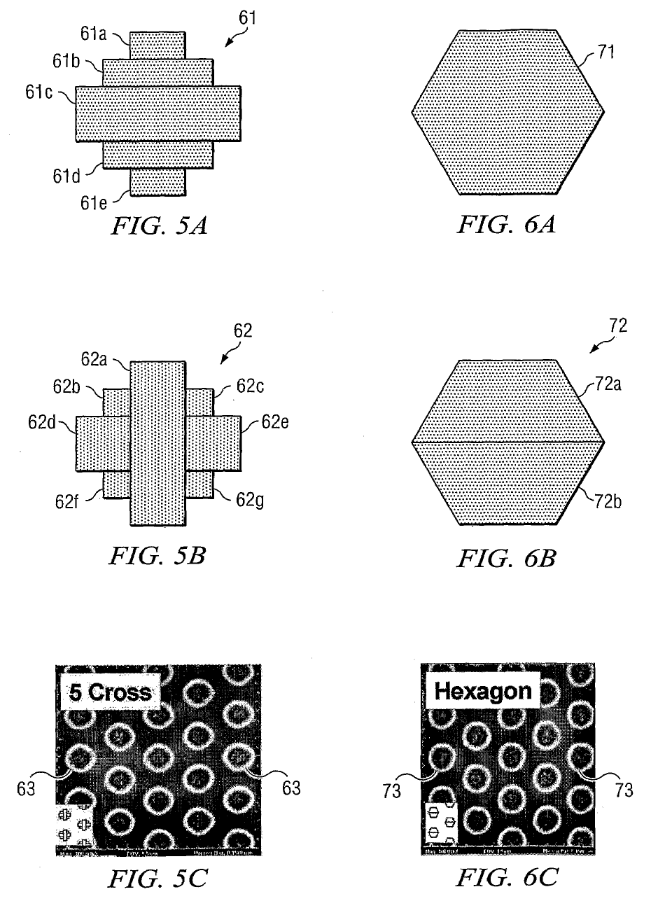

FIG. 5A illustrates five-figure cross feature 61 included in a mask layout file. Five-figure cross feature 61 may be a primitive shape created by drawing five rectangles 61a-61e either as shown or rotated. For example, five-figure cross feature 61 may be created by drawing rectangle 61c oriented horizontally, two smaller rectangles 61b and 61d oriented horizontally on either side of first rectangle 61b, one smaller rectangle 61a on the top side of rectangle 61b and another smaller rectangle 61e on the bottom side of rectangle 61d. Alternatively, five-figure cross feature 61 may be drawn as a single large rectangle with a smaller rectangle drawn on each of the four sides of the large rectangle. In other embodiments, five-figure cross feature 61 may be drawn as three overlaid rectangles. In one embodiment, five-figure cross feature 61 may represent a feature with approximately equal length and width. Five-figure cross feature 61 may have critical dimensions, such as length and width of rectangles 61a-61e, ranging from approximately 120 nm to approximately 300 nm. Five-figure cross feature 61 may also be drawn such that the length and width of the rectangles vary independently of one another and are not approximately equal. Other dimensions of the feature may also be altered depending on the desired shape of the feature on the photomask.

FIG. 5B illustrates five-figure cross feature 61 after being fractured to create writeable image 62 in a mask pattern file. In one embodiment, five-figure cross feature 61 may consistently fracture into seven writeable shapes 62a-62g to form writeable image 62. The exact configuration of the writeable shapes may vary in different embodiments of the disclosure. For example, writeable image 62 may be fractured into rectangle 62a oriented vertically with three smaller rectangles 62b, 62d, and 62f on one side of first rectangle 62a, and three smaller rectangles 62c, 62e, and 62g on the other side of first rectangle 62a. In another embodiment, writeable image 62 may be fractured into a large rectangle oriented horizontally and three smaller rectangles located both above and below the first rectangle. A lithography system using a mask pattern file containing writeable image 62, therefore, may use as few as between five and seven exposures to print five-figured cross feature 61 on photomask 12.

FIG. 5C illustrates five-figured cross feature 61 formed on a photomask. In the illustrated embodiment, a mask pattern file including multiple five-figured cross features 61 in an offset pattern was used to form a patterned layer including non-orthogonal features 63 on a photomask substrate. At sizes between approximately 120 nm and approximately 300 nm, writeable image 62 may print as non-orthogonal feature 63 that approximates a diamond in shape but has rounded points. Thus, five-figured cross feature 61 in a mask layout file may be used to create a diamond-like feature or slight variations of that shape on a photomask.

FIG. 6A illustrates hexagon feature 71 included in a mask layout file. Hexagon feature 71 may be a e primitive shape, and may be drawn simply as a hexagon. In one embodiment, hexagon feature 71 may have approximately equal side lengths. In another embodiment, hexagon feature 71 may also be drawn such that side lengths vary independently of one another and are not approximately equal. A critical dimension of hexagon feature 71 (e.g., a diameter measured between two opposite points or a diameter measured between opposite vertical sides) may be between approximately 120 nm and approximately 300 nm.

FIG. 6B illustrates hexagon feature 71 after being fractured to create writeable image 72 in a mask pattern file. In one embodiment, hexagon feature 71 may consistently fracture into two writeable shapes 72a and 72b, both trapezoids, to form writeable image 72. The exact configuration of the writeable shapes may vary in different embodiments. A lithography system using a mask pattern file containing writeable image 72, therefore, may use as few as two exposures to print hexagon feature 71 on photomask 12. Because a primitive shape, such as hexagon feature 71, may fracture into a reduced number of writeable shapes, the number of exposures needed from the lithography system may be reduced. A smaller number of exposures may result in increased production speed and lower costs.

FIG. 6C illustrates hexagon feature 71 formed on a photomask. In the illustrated embodiment, a mask pattern file including multiple hexagon features 71 in an offset pattern was used to form a patterned layer including non-orthogonal features 73 on a photomask substrate. At sizes between approximately 120 nm and approximately 300 nm, writeable image 72 may print as non-orthogonal feature 73 that approximates a circle in shape. Thus, hexagon feature 71 in a mask layout file may be used to create circular feature 73 or slight variations of that shape on a photomask. By using hexagon feature 71, circular feature 73 may be created with as few as two exposures, as compared with at least twenty-three exposures for the feature shown in FIG. 2B. This may result because hexagon feature 71 may fracture into as few as two writeable shapes each requiring one exposure to form, while circular feature 31 may fracture into at least twenty-three writeable shapes each requiring one exposure to form.

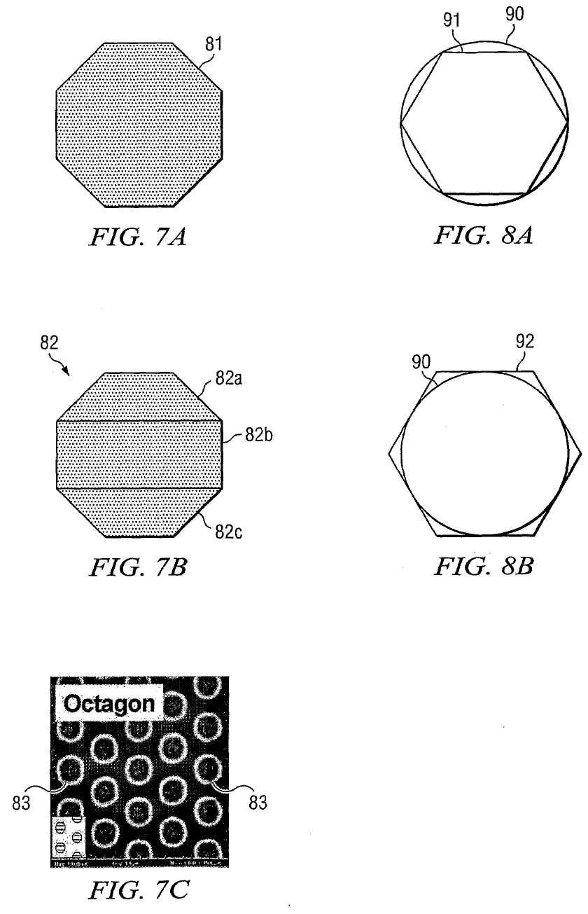

FIG. 7A illustrates octagon feature 81 included in a mask layout file. Octagon feature 81 may be a primitive shape, and may be drawn simply as an octagon. In one embodiment, octagon feature 81 may have approximately equal side lengths. In another embodiment, octagon feature 81 may also be drawn such that side lengths vary independently of one another and are not approximately equal. For example, an octagon feature that has a disproportionate length and width may be used to form an elliptical and/or oval feature on a photomask. A critical dimension of hexagon feature 81 (e.g., a diameter measured between two opposite points or a diameter measured between opposite vertical sides) may be between approximately 120 nm and approximately 300 nm.

FIG. 7B illustrates octagon feature 81 after being fractured to create writeable image 82 in a mask pattern file. In one embodiment, octagon feature 81 may consistently fracture into three writeable shapes, a rectangle 82b and two trapezoids 82a and 82c, to form writeable image 82. Rectangle 82b may be located between trapezoids 82a and 82c. The exact configuration of the writeable shapes may vary in different embodiments. A lithography system using a mask pattern file containing writeable image 82, therefore, may use as few as three exposures to print octagon feature 81 on photomask 12.

FIG. 7C illustrates octagon feature 81 formed on a photomask. In the illustrated embodiment, a mask pattern file including multiple octagon features 81 in an offset pattern was used to form a patterned layer including non-orthogonal features 83 on a photomask substrate. At sizes between approximately 120 nm and approximately 300 nm, writeable image 82 may print as non-orthogonal feature 83 that approximates a circle in shape. Thus, octagon feature 81 in a mask layout file may be used to create a circular feature or slight variations of that shape on a photomask.

FIGS. 8A and 8B illustrate techniques for sizing a hexagon feature according to different embodiments of the disclosure. Turning first to FIG. 8A, the figure shows circular feature 90 having a diameter between approximately 120 and approximately 300 nm. Circular feature 90 may be drawn in a mask layout file. This feature is used in the current example for reference, and will not be imaged onto the photomask. In one embodiment, hexagon feature 91 is drawn inside circular feature 90 and has corners intersecting the circumference of circular feature 90. Hexagon feature 91 may be included in a mask layout file and fractured into writeable shapes, as discussed above in reference to FIG. 6B. The resulting mask pattern file may be imaged onto a photomask blank and developed in order to form a circular feature on a photomask. In one embodiment, the diameter of the developed circular feature on the photomask may be less than the diameter of circular feature 90.

Turning now to FIG. 8B, circular FIG. 90 may be drawn in a mask layout file and has a diameter between approximately 120 and approximately 300 nm. This feature is used for reference, and will not be developed. In contrast to embodiment discussed in reference to FIG. 8A, hexagon feature 92 is sized such that the sides of hexagon feature 92 contact the circumference of circular feature 90. Hexagon feature 92 may be included in a mask layout file and fractured into writeable shapes. The resulting mask pattern file may be imaged onto a photomask blank and developed in order to form a circular feature on a photomask. In one embodiment, the diameter of the developed circular feature on the photomask may be approximately the same as the diameter of circular feature 90. This technique for drawing and sizing features in a mask layout file may allow a user to conveniently approximate the actual size of a developed feature on a photomask.

Although the present disclosure as illustrated by the above embodiments has been described in detail, numerous variations will be apparent to one skilled in the art. For example, the size and shape of the features created in a mask layout file may be varied to produce desired non-orthogonal features on a photomask. The non-orthogonal features may also be formed by the absorber layer or by exposed portions of the photomask substrate. It should be understood that various changes, substitutions and alternations can be made herein without departing from the spirit and scope of the disclosure as illustrated by the following claims.

What is claimed is:

1. A method for forming a non-orthogonal feature on a photomask blank, comprising:
providing a mask layout file including a primitive shape;
fracturing the primitive shape to create a plurality of writeable shapes in a mask pattern file; and
forming a non-orthogonal feature on a photomask blank by using a lithography system to image the writeable shapes from the mask pattern file onto a resist layer of the photomask blank, the writeable shapes forming a non-orthogonal feature on the photomask blank.

2. The method of claim 1, wherein the non-orthogonal feature is selected from the group consisting of a circle, a diamond, an ellipse and an oval.

3. The method of claim 1, wherein the non-orthogonal feature includes a critical dimension between approximately 120 nm and approximately 300 nm.

4. The method of claim 3, wherein the non-orthogonal feature comprises a circle, an ellipse or an oval and the critical dimension is a diameter of the circle or the ellipse.

5. The method of claim 3, wherein the non-orthogonal feature comprises a diamond and the critical dimension is a length of a side of the diamond.

6. The method of claim 1, wherein the primitive shape is selected from the group consisting of a cross, a five-figure cross, a hexagon, and an octagon.

7. The method of claim 1, wherein the plurality of writeable shapes comprises two trapezoids.

8. The method of claim 1, wherein the plurality of writeable shapes comprises less than approximately ten writeable shapes.

9. The method of claim 1, wherein the lithography system is selected from the group consisting of an electron beam lithography tool, a laser lithography tool, and an x-ray lithography tool.

10. The method of claim 1, wherein the non-orthogonal feature is formed with less than approximately ten exposures of the lithography system.

11. A method for forming a non-orthogonal feature on a photomask, comprising:
exposing a resist layer of a photomask blank with a first portion of a primitive shape;
exposing the resist layer with at least a second portion of the primitive shape, the second portion located adjacent to the first portion; and
developing the resist layer to form a non-orthogonal feature having critical dimensions between approximately 120 and approximately 300 nm, the first and second portions of the primitive shape forming a non-orthogonal feature.

12. The method of claim 11, wherein the non-orthogonal feature is selected from the group consisting of a circle, a diamond, an ellipse and an oval.

13. The method of claim 11, wherein the first and second portions of the primitive shape are comprised of at least one of a rectangle, a trapezoid, and a triangle.

14. The method of claim 11, wherein the primitive shape is selected from the group consisting of a cross, a five-figure cross, a hexagon, and an octagon.

15. The method of claim 11, wherein the non-orthogonal feature is formed with less than approximately ten exposures of a lithography system.

16. A photomask for forming a non-orthogonal feature on a surface, comprising:
a substrate; and
a patterned layer formed on at least a portion of the substrate, the patterned layer including a non-orthogonal feature formed with a lithography system by using a primitive shape fractured into at least two writeable shapes.

17. The photomask of claim 16, wherein the non-orthogonal feature is selected from the group consisting of a circle, a diamond, an ellipse, and an oval.

18. The photomask of claim 16, wherein the primitive shape is selected from the group consisting of a cross, a five-figure cross, a hexagon, and an octagon.

19. The photomask of claim 16, wherein each of the at least two writeable shapes comprises at least one of a trapezoid, a rectangle, or a triangle.

20. The photomask of claim 16, wherein the non-orthogonal feature has a critical dimension between approximately 120 and approximately 300 nm.

21. The photomask of claim 20, wherein the critical dimension is either the length, width, or diameter of the non-orthogonal feature.

22. The photomask of claim 16, further comprising a pellicle assembly coupled to the substrate.
